(19) United States
(12) Patent Application Publication
(10) Pub. No.: US 2012/0181686 A1
(43) Pub. Date: Jul. 19, 2012

(54) METHOD OF PREPARING SEMICONDUCTOR PACKAGE AND SEMICONDUCTOR DIE FOR SEMICONDUCTOR PACKAGE

(75) Inventors: Joon Yong PARK, Suwon-si (KR); Yong Seok HAN, Anyang-si (KR); Jae Jun LEE, Suwon-si (KR); Chul Ho JEONG, Gwangju (KR)

(73) Assignee: SAMSUNG ELECTRONICS CO., LTD., Suwon-si (KR)

(21) Appl. No.: 13/303,938

(22) Filed: Nov. 23, 2011

(30) Foreign Application Priority Data
Jan. 19, 2011 (KR) 10-2011-0005596

(51) Int. Cl. H01L 23/498; H01L 21/56

(52) U.S. Cl. 257/737; 438/107; 257/E21.504; 257/E23.068

(57) ABSTRACT

A method of preparing a semiconductor package including disposing photosensitive adhesive film on a reinterconnected rear surface of a wafer on which the through electrodes are disposed, and forming a pattern corresponding to the through electrodes to prepare the semiconductor package.

### CROSS-REFERENCE TO RELATED APPLICATION

This application claims priority to Korean Patent Application No. 10-2011-0005596, filed on Jan. 19, 2011, and all the benefits accruing therefrom under 35 U.S.C. §119, the content of which in its entirety is herein incorporated by reference.

### BACKGROUND

1. Field

This disclosure relates to a method of preparing a semiconductor package and a semiconductor die for use in the semiconductor package.

2. Description of the Related Art

In recent years, various semiconductor packages for high semiconductor device integration and capacity have been developed. In semiconductor packages, a patternable adhesive film is used to adhere a semiconductor die to a support substrate and/or to adhere a semiconductor die to another semiconductor die. Development of a through-silicon-via (“TSV”) technique which includes forming through electrodes and then providing a 3-dimensional stack structure, has progressed. The TSV technique is regarded as a technique which can overcome the restrictions of wire-bonding, which is presently the most popular chip package technique, including restrictions such as 2-dimensional shrinkage, 3-dimensional form factor, and restricted communication speed between semiconductor dies. The TSV technique using the through electrodes may involve interposing a patternable adhesive film between semiconductor dies.

To use a patternable adhesive film on a semiconductor die with the TSV technique, the patternable adhesive film desirably provides high-temperature adhesiveness. While a number of adhesive films are known in the art, there remains a need for an improved method for preparing a semiconductor package.

### SUMMARY

A method of preparing a semiconductor package is disclosed.

In an aspect, a method of preparing a semiconductor package includes disposing a photosensitive adhesive film on a reinterconnected rear surface of a wafer on which through electrodes are disposed; and forming a pattern corresponding to the through electrodes to prepare the semiconductor package.

The method may further include: temporarily bonding a transparent support to a front surface of the wafer on which the through electrodes are disposed; lapping an opposite rear surface of the wafer; reinterconnecting the opposite rear surface of the wafer; laminating a second photosensitive adhesive film on the reinterconnected rear surface of the wafer; exposing and alkali developing the second photosensitive adhesive film to form a pattern corresponding to the through electrodes; bonding a dicing tape to the rear surface of the wafer on which the pattern of the second photosensitive adhesive film is formed; detaching the transparent support from the front surface of the wafer; dicing the wafer to form a plurality of semiconductor dies having a predetermined size; removing the dicing tape; and stacking and bonding the plurality of semiconductor dies.

According to another aspect, the method may further include, before the lapping and reinterconnecting of the opposite rear surface of the wafer, laminating a first photosensitive adhesive film on the front surface of the wafer on which the through electrodes are disposed, and exposing and alkali developing the first photosensitive adhesive film to form a pattern corresponding to the through electrodes.

Also, a semiconductor die for a semiconductor package is also disclosed.

According to an aspect, a semiconductor die for a semiconductor package includes a a first pattern adhesive film disposed on a front surface; and second pattern adhesive layer comprising a pattern and disposed on an opposite rear surface thereof, wherein pads of through electrodes are reinterconnected in the pattern.

According to another embodiment, a first pattern adhesive layer on which a pattern is formed, may be disposed on a front surface of the semiconductor die, and through electrodes on which solder bumps are disposed may be disposed in the pattern.

In a method of preparing a semiconductor package, a photosensitive adhesive film may be disposed not only on a front surface of a wafer but also disposed on a reinterconnected rear surface thereof. Alternatively, the photosensitive adhesive film may be disposed only on a reinterconnected rear surface of the wafer. Thus, by laminating a new patternable adhesive film after reinterconnecting the rear surface of the wafer, adhesive strength between semiconductor dies may be maintained. As a result, and without being bound by theory, it is thought a prepared semiconductor package may be prevented from interfacial delaminating during a reliability test.

### BRIEF DESCRIPTION OF THE DRAWINGS

The above and other aspects, advantages and features of this invention will become more apparent by describing in further detail exemplary embodiments thereof with reference to the accompanying drawings, in which:

FIGS. 1 to 5 are schematic diagrams sequentially showing an embodiment of a method of preparing a semiconductor package, respectively; and

FIG. 6 is a cross-sectional view of a semiconductor die for a semiconductor package according to an exemplary embodiment.

### DETAILED DESCRIPTION

The invention now will be described more fully hereinafter with reference to the accompanying drawings, in which a non-limiting embodiment is shown. This invention may, however, be embodied in many different forms, and should not be construed as limited to the example embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated regions, integers, steps, operations, elements, and/or components, but do not preclude the presence or addition of one or more other regions, integers, steps, operations, elements, components, and/or groups thereof.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore encompass both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

One or more embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear portions. Moreover, sharp angles that are illustrated may be rounded. Thus, the regions illustrated in the figures are schematic in nature and their shapes are not intended to illustrate the precise shape of a region and are not intended to limit the scope of the claims.

According to an embodiment, a method of preparing a semiconductor package includes providing a wafer on which through electrodes are disposed, disposing a photosensitive adhesive film on a reinterconnected rear surface of the wafer, and forming a pattern corresponding to the through electrodes using a photosensitive adhesive film which is applied to a rear surface of a reinterconnected wafer.

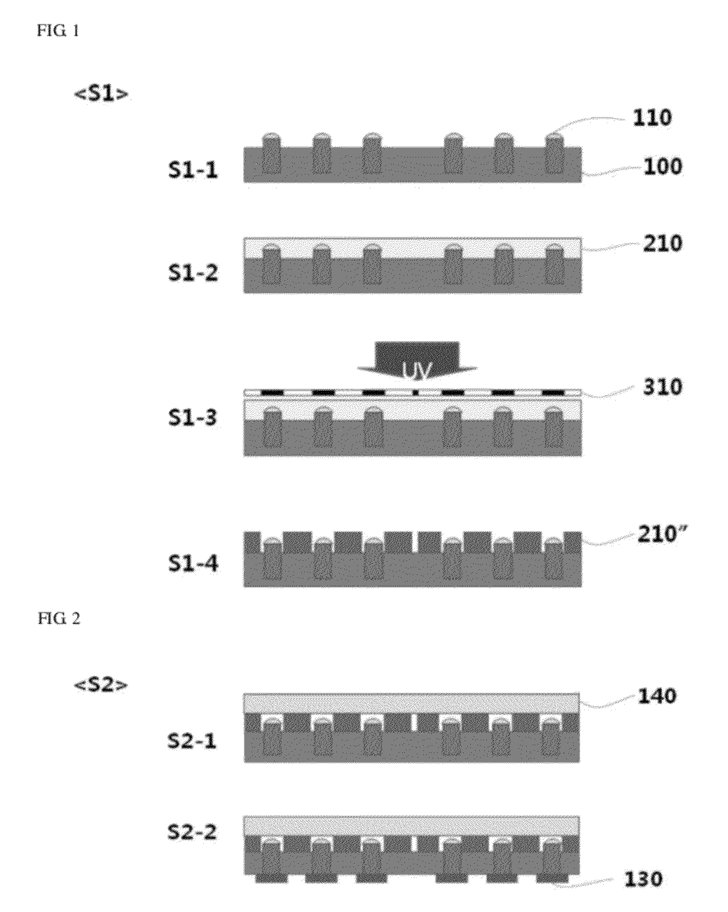

FIGS. 1 to 5 are schematic diagrams sequentially showing a method of preparing a semiconductor package by laminating patternable adhesive films on front and opposite rear surfaces of a wafer according to an embodiment. Referring to FIGS. 1 to 5, the method of preparing the semiconductor package may comprise:

laminating a first photosensitive adhesive film 210 on a front surface of a wafer 100 on which through electrodes 110 are disposed, and then exposing and alkali developing the first photosensitive adhesive film 210 to form a pattern 210″ corresponding to the through electrodes 110 (S1);

temporarily bonding a transparent support 140 to the front surface of the wafer 100 on which the first pattern 210″ is formed; lapping an opposite rear surface of the wafer 100; reinterconnecting the opposite rear surface of the wafer 100 (S2);

laminating a second photosensitive adhesive film 220 on the reinterconnected rear surface of the wafer 100; and then exposing and alkali developing the second photosensitive adhesive film 220 to form a second pattern 220″ corresponding to the reinterconnected rear surface of the wafer (S3);

bonding a dicing tape 150 to the rear surface of the wafer 100 on which the pattern 220″ is formed; detaching the transparent support 140 from the front surface of the wafer 100; dicing the wafer 100 to form a plurality of semiconductor dies, e.g., first and second semiconductor dies 410 and 420, respectively, each independently having a predetermined size; removing the dicing tape 150 (S4); and stacking and bonding the plurality of semiconductor dies to manufacture the semiconductor package 500 (S5).

According to another embodiment, a photosensitive adhesive film may be laminated only on the rear surface of the wafer 100. In such an embodiment, the method of preparing the semiconductor package may begin from step S2 and step S1 may omitted. Thus, in an embodiment the method may comprise lapping and reinterconnecting the rear surface of the semiconductor wafer 100, without the pattern 210″ which is formed by the first photosensitive adhesive film 210 on the front surface of the wafer, and then laminating the second photosensitive adhesive film 220 on the rear surface of the semiconductor wafer.

Conventionally, a pattern may be formed by laminating a patternable adhesive film on a front surface of a wafer, and semiconductor dies may be bonded to each other using the patternable adhesive film. However, the adhesive strength of the adhesive film may be lost upon exposure to ultraviolet (“UV”) light during the thinning and reinterconnecting of the wafer on a wafer level.

According to the above embodiment, the reinterconnecting may be followed by laminating a patternable adhesive film only on the rear surface of the wafer or laminating patternable adhesive films on both the front and opposite rear surfaces of the wafer. Accordingly, it was discovered that laminating a patternable adhesive film on the rear surface of the wafer may effectively eliminate or overcome reduction in the adhesive strength of the patternable adhesive films, and as a result, adhesive strength between semiconductor dies may be maintained. While not wanting to be bound by theory, it is believed that adhesive strength reduction may be the result of a high-temperature condition, which is desirable for the reinterconnecting of the through electrodes disposed on the rear surface of the wafer 100, and/or UV irradiation, which is useful for detaching a temporary adhesive tape and transparent support which may be temporarily bonded to the front surface of the wafer, and configured to support the wafer to enable handling of the wafer. As a result, in the disclosed method the adhesive strength between dies may be maintained.

### Manufacture of a Semiconductor Package

Step S1 as shown in FIG. 1, may be performed as follows.

First, a wafer 100 on which through electrodes 110 are disposed is provided (S1-1). Solder bumps are disposed on the top ends of the through electrodes 110. The solder bumps are protrusions, which comprise tin (Sn) and lead (Pb), for example. Next, a first photosensitive adhesive film 210 is laminated on the front surface of the wafer 100 (S1-2). The lamination of the first photosensitive adhesive film 210 may be performed by a known coating process, such as a dipping process, a spin coating process, or a roll coating process, but not limited thereto, the details of which may be determined without undue experimentation.

Next, a negative pattern 210″, corresponding to the through electrodes 110 (S1-4) may be disposed using ultraviolet (“UV”) exposure and alkali developing processes (S1-3). Before the UV exposing, a pre-baking process may be performed at a temperature of about 60 to about 120° C., or about 65 to about 110° C., or about 70 to about 100° C. for about 1 to about 30 minutes, or about 2 to about 25 minutes, or, about 4 to about 20 minutes, if desired. For example, the pre-baking may be performed at a temperature of about 80° C. for about 10 minutes, more preferably about 90° C. for about 2 minutes, still more preferably about 100° C. for about 2 minutes.

The UV exposing process may be performed using a photomask 310 having portions of negative-treated electrodes with the same arrangement as the through electrodes disposed on the front surface of the wafer. The UV exposing process may be performed at an exposure dose of about 10 to about 3000 milliJoules per square centimeter (mJ/cm²), more preferably about 500 to about 2000 mJ, and still more preferably about 1000 to about 2500 mJ/cm² based on an Hg i-line. After exposing, post-baking process may be performed which may comprise heating at a temperature of about 60 to about 120° C., or about 65 to about 110° C., or about 70 to about 100° C. for about 1 to about 30 minutes, or about 2 to about 25 minutes, or about 4 to about 20 minutes, to increase developing sensitivity. For example, the wafer may be irradiated by UV light having a wavelength of 365 nanometers (nm), and then post-baked at a temperature of about 100° C. for about 2 minutes.

The alkali developing process may include removing the non-exposed portion of the film using a developing solution. The developing process may be any known developing process including a puddle development method, a dipping method, a paddle method, a spray method, or a shower development method. After the alkali developing process, the developed film may be washed with water for about 30 seconds to about 360 seconds, and may then be air-dried using an air arm or hot-air dried using a hot plate or oven. A developing solution used during alkali developing, may be an alkali developing solution such as an alkali aqueous solution. The alkali developing solution may comprise at least one compound selected from an alkali metal salt such as sodium hydroxide, potassium hydroxide, sodium carbonate, sodium silicate, or sodium metasilicate; ammonia; an alkyl amine such as ethyl amine, n-propyl amine, diethyl amine, di-n-propyl amine, triethyl amine, or methyl diethyl amine; an alkanol amine such as dimethyl ethanol amine or triethanol amine; a heterocyclic amine such as pyrrole or piperidine; a tetraalkylamomonium hydroxide such as tetramethylammonium hydroxide or tetraethylammonium hydroxide; and an alkali compound such as a choline, 1,8-diazabicyclo [5.4.0]-7-undecene, and 1,5-diazabicyclo[4.3.0]-5-nonene. The alkali developing solution may further comprise a water-soluble organic solvent, such as methanol or ethanol, and/or a surfactant.

The through electrodes may be miniaturized such that about at least 500 through electrodes per semiconductor die are provided to form input/output (“I/O”). Accordingly, the pattern may be an alkali-developable negative pattern, which has a diameter of about 100 micrometers (μm) or less, about 70 μm or less, or about 50 μm or less, an aperture ratio of about 5% or less, or at least 500 to 10000 through electrodes per semiconductor die.

If necessary, the wafer may be rinsed and dried to remove the remaining developing solution and a non-exposed portion of the film. For example, the wafer may be spun using a 2.38 percent by weight (% by weight) tetramethylammoniumhydroxide (“TMAH”) alkali developing solution at room temperature for about 60 seconds, rinsed with deionized water (“DIW”), and then dried, to form a pattern having 95% of the dimension linearity on a photomask.

Step S2 as shown in FIG. 2, may be performed as follows.

To facilitate the handling of the wafer, a transparent support 140 may be temporarily bonded to the front surface of the wafer on which the pattern is optionally formed in S1 (S2-1). The transparent support 140 may be transparent so as to facilitate irradiating the wafer with UV light, flattened to prevent the rolling of a semiconductor wafer, and have a predetermined strength. The transparent support 140 may comprise a water resistant material, and a temporary adhesive tape may be bonded to the transparent support 140.

Thereafter, an opposite rear surface of the wafer may be lapped to protrude the through electrodes from the rear surface of the wafer, and reinterconnected (S2-2). For example, after the opposite rear surface of the wafer is lapped to expose the through electrodes, a sputtering process may be performed to form a metal layer pattern 130, which enables the reinterconnecting of the rear surface of the wafer. Thereafter, a passivation layer may be disposed by a chemical vapor deposition (“CVD”) process.

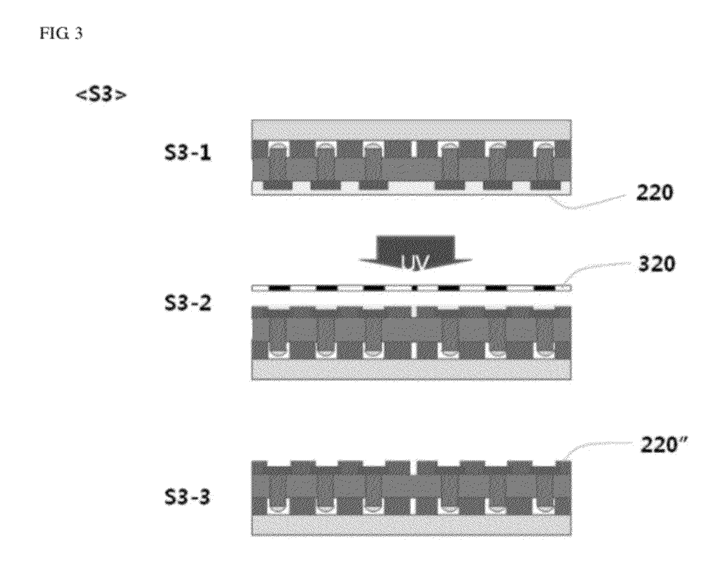

Step S3 as shown in FIG. 3, may be performed as follows.

A second photosensitive adhesive film 220 may be laminated on the reinterconnected opposite rear surface of the wafer 100 as prepared in S2 (S3-1). In this embodiment, a thickness of the second photosensitive adhesive film may be about ⅕ to about 1 times that of the first photosensitive adhesive film 210. When the through electrodes are disposed on the front surface of the wafer, solder bumps may be disposed on the top ends of the through electrodes using a plating process, wherein the solder bumps have a thickness of about 10 micrometers (μm) or more, or 1 to 100 μm, or 10 to 50 μm. However, it may be difficult to dispose electrode pads having a thickness of several μm or more, wherein the electrode pads are formed by the reinterconnecting of the opposite rear surface of the wafer. Accordingly, the thickness of the first and/or second photosensitive adhesive films disposed on the front and/or rear surfaces of the wafer may be at least about 20% thicker than the total thickness of the solder bumps in order to prevent the solder bumps from being broken during laminating. Further, the thickness of the second photosensitive adhesive film disposed on the opposite rear surface of the wafer may be thinner than the first photosensitive adhesive film.

Thereafter, exposing and alkali developing of the film are performed (S3-2). The exposing may be performed using a photomask 320 having portions of negative-treated portions with the same arrangement as the through electrodes disposed on the opposite rear surface of the wafer. Thus, a negative pattern 220″ corresponding to the through electrodes 110 is disposed on the film (S3-3). The laminating, exposing, and developing processes are as in S1. As above, pre-baking may be performed before exposing, and post-baking may be performed after the exposing. Also, rinsing and drying of the wafer may be performed after developing.

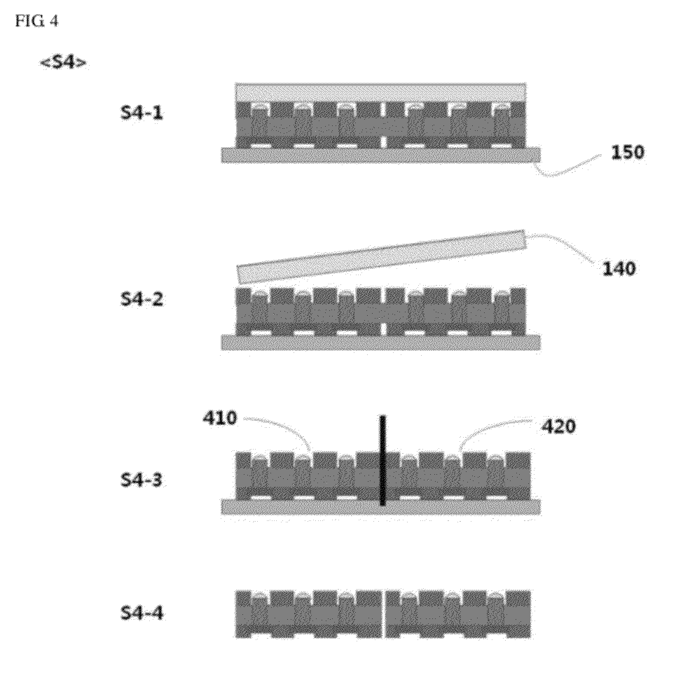

Step S4, as shown in FIG. 4, may be performed as follows.

To facilitate the handling and dicing of the wafer, a dicing tape 150 is bonded to the rear surface of the wafer on which the negative pattern is formed in S3 (S4-1). Afterwards, the temporarily bonded transparent support 140 is detached from the front surface of the wafer (S4-2). The transparent support 140 may be detached from the wafer by exposing a temporary adhesive tape with UV irradiation, thereby removing adhesive strength of the tape. Thereafter, the wafer is diced to form a plurality of semiconductor dies, such as a first semiconductor die 410 and a second semiconductor die 420 having a predetermined size (S4-3). A method for dicing the wafer into the semiconductor dies is not especially limited, but may be performed by a known process for dicing a lapped rear surface of a wafer, for example, such as a blade sawing process or a stealth dicing method. The stealth dicing method may comprise exposing the wafer to a focused laser to cause cracks within the wafer under the dicing tape, and expanding the wafer using a wafer expansion process, thereby inducing the dicing of the wafer, which may considerably reduce the breakage of the wafer as compared with conventional methods. After dicing the wafer, to facilitate a subsequent pickup of the semiconductor dies, the temporarily bonded dicing tape 150 may be irradiated using UV light, thereby removing the adhesive strength of the tape 150 (S4-4).

After S4, the semiconductor dies for semiconductor packages are manufactured. In an embodiment, each semiconductor die has a front surface on which a first pattern adhesive layer 510 is disposed. The first pattern adhesive layer comprises the first pattern 210″, which is derived from first adhesive film 210, and through electrodes having solder bumps disposed on the top ends of the through electrodes. Each semiconductor die also has an opposite reinterconnected rear surface on which a second pattern adhesive layer 520 is disposed, the second pattern adhesive layer 520 comprising the second pattern 220″, which is derived from the second adhesive film 220, and pads of the reinterconnected through electrodes.

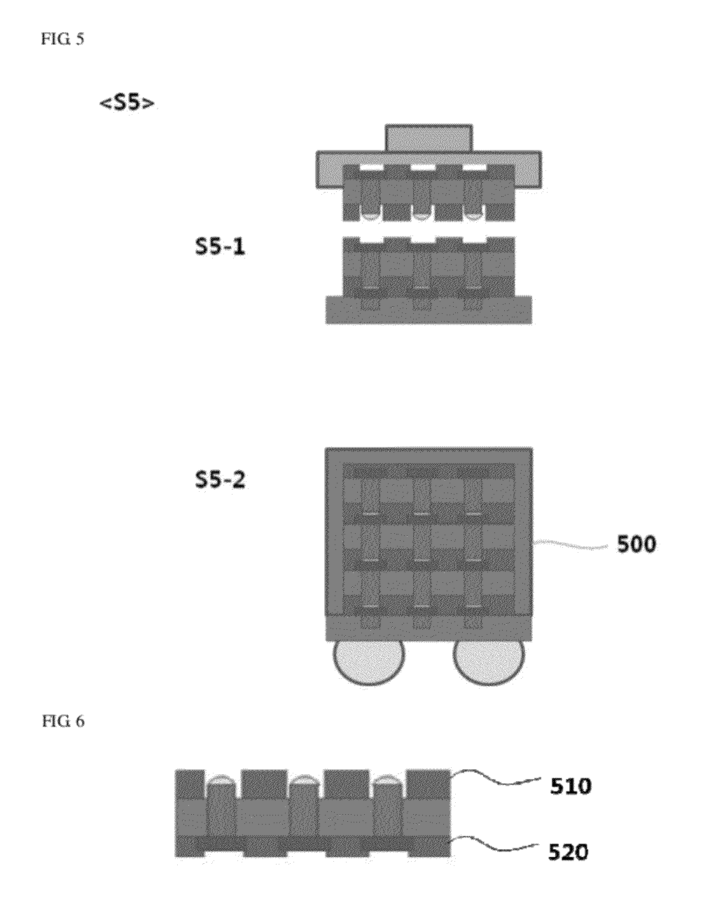

Step S5 as shown in FIG. 5, may be performed as follows.

A plurality of semiconductor dies provided in S4 may be bonded to each other, after stacking at least two semiconductor dies on each other. For example, the front surface of the first semiconductor die may be bonded to the rear surface of the second semiconductor die having a shape corresponding thereto, and then the first and second semiconductor dies may be bonded to each other by soldering the through electrodes at a temperature of about 260° C. and by simultaneously thermally curing the first and second photosensitive adhesive films. Since the previously opened electrodes may be bonded using the solder bumps, the electrodes may be bonded under a low bonding pressure, e.g., a pressure of about 1 kilogram force (kgf) or less, or about 0.01 kgf to about 1 kgf, or about 0.1 to about 0.5 kgf. Even when the through electrodes are bonded under a high pressure, it is less likely to break the first and second semiconductor dies. Accordingly, the through electrodes may be bonded using the solder bumps at a temperature of about 260° C. for about 20 seconds or less, or at a temperature of about 200 to about 260° C. for about 1 to about 30 seconds under a pressure of about 0.1 to about 10 kgf, or 0.5 to about 5 kgf.

Optionally, after at least two semiconductor dies are stacked on each other, the method of manufacturing the semiconductor dies may further include treating a stacked structure of the at least two semiconductor dies using an epoxy molding compound (“EMC”) and hard baking at a temperature of about 150 to about 190° C. for about 1 to about 3 hours (S5-2).

The above first and second photosensitive adhesive films 210 and 220 may exhibit adhesiveness by a thermal curing process and have photosensitivity such that through hole patterns are formed along the patterns of the through electrodes on the front surface of the wafer. These photosensitive films are not especially limited, and may be any known film having photosensitivity and adhesiveness.

According to an embodiment, the first and second photosensitive adhesive film may be prepared by applying a patternable adhesive composition on a base material having an appropriate thickness, and then removing a solvent.

For example, the base film may be polyethyleneterephthalate (“PET”), but is not limited thereto. A method of applying a patternable adhesive composition may be performed by a known coating process. The solvent may be volatilized at a temperature of, for example, about 30 to about 150° C. for about 1 minute to about 2 hours.

The patternable adhesive composition may include: at least one alkali soluble resin A comprising at least one alkali soluble group and an acryloyl group; at least one radically polymerizable compound B; at least one thermosettable compound C; and at least one photo-radical initiator D.

A thickness variation of the photosensitive adhesive film formed using the patternable adhesive composition and after exposing the photosensitive adhesive film to a radiation source to crosslink an exposed portion of the film and developing the exposed photosensitive adhesive film may be less than about 5%, or about 0.1 to about 5%, or about 0.5 to about 4%. For example, when the exposed portion is exposed for about 200 seconds at a radiation dose of about 500 to about 3000 milliJoules per square centimeter (mJ/cm²) at a wavelength of 365 nanometers (nm) using an i-line of a Hg lamp as a UV light source, which can irradiate fine patterns, a thickness variation of the exposed portion of the photosensitive adhesive film formed using the patternable adhesive composition may be less than 5%, or about 0.1 to about 5%, or about 0.5 to about 4%. After developing the exposed portion, if a thickness variation of the exposed portion is 5% or more, the surface of the exposed portion may be undesirably affected by a developing solution. Accordingly, the patternable adhesive composition may not have sufficient dimensional stability for a patternable adhesive film, the roughness of the patternable adhesive composition may also be unsuitable, and air bubbles may be generated during a final thermal adhesion process.

A non-exposed portion of the photosensitive adhesive film formed using the patternable adhesive composition may be dissolved at a rate of at least about 0.1 micrometer per second (μm/sec) or at least about 0.4 μm/sec or higher, or at about 0.1 to about 100 μm/sec, and even more specifically at about 1 to about 10 μm/sec when contacted with a 2.38% by weight tetramethylammonium hydroxide (“TMAH”) developing solution.

The patternable adhesive composition may form a negative pattern around a through electrode having a pitch and diameter of several tens of micrometers (μm), e.g. about 1 to about 100 μm, or about 5 to about 80 μm, and more specifically about 10 to about 60 μm, using an alkali developing solution. Thus, to form at least several hundreds of input/output (“I/O”) electrodes per semiconductor die in a semiconductor package, the through electrode may be miniaturized and used to form a pattern having a pitch and diameter of several tens of μm, e.g., about 1 to about 100 μm, or about 5 to about 80 μm, and more specifically about 10 to about 60 μm.

Also, the patternable adhesive composition may have a shear bond strength of about 3 kilograms force per 25 square millimeters (kgf/mm²) or more, or about 3 to about 30 kgf/25 mm², or about 4 to about 20 kgf/25 mm², or about 8 kgf/25 mm² or more, when cured at a temperature of about 260° C. Accordingly, the patternable adhesive composition may be used to provide a film that exhibits reliability within several seconds when used for bonding between semiconductor dies.

In addition, since the patternable adhesive composition has photosensitive characteristics and can be developed with an aqueous alkali solution, the patternable adhesive composition may be more environment-friendly than a developing system using other organic solvents.

In the patternable adhesive composition, a content of a solid component may be included in an amount of about 1 to 40 parts by weight, or about 2 to about 35 parts by weight, or about 4 to about 30 parts by weight of a solid component, based on 100 parts by weight of an organic solvent. The combination of the solid component and the organic solvent may form a solution, a suspension, or a combination thereof. For example, the patternable adhesive composition may comprise about 30 to about 95 percent by weight (% by weight), or about 50 to about 80% by weight, or about 55 to about 75% by weight of alkali soluble resin A; about 0.1 to about 20% by weight, or about 1 to about 10% by weight, or about 2 to about 8 by weight of the radically polymerizable compound B; about 0.1 to about 10% by weight, or about 1 to about 5% by weight, or about 1 to about 10% by weight of the photo-radical initiator D; and about 1 to about 60% by weight, or about 5 to about 40% by weight, or about 10 to about 30% by weight of thermosettable compound C, each based on a total weight of the patternable adhesive composition exclusive of the solvent, if present.

A suitable solvent may be selected and used as the organic solvent to uniformly dissolve or disperse the solid component, e.g., the alkali soluble resin A, the radically polymerizable compound B, the thermosettable compound C, and the photo-radical initiator D. For example, the organic solvent may be at least one selected from dimethyl formamide, dimethyl sulfoxide, toluene, benzene, xylene, methyl ethyl ketone, tetrahydrofuran, ethyl acetate, ethyl cellosolve, ethyl cellosolve acetate, dioxane, cyclohexane, N-methyl-pyrrolidinone, and the like.

Hereinafter, respective components of the patternable adhesive composition according to an embodiment will be further disclosed.

### Alkali Soluble Resin A

The alkali soluble resin A may comprise an acryloyl group having a carbon-carbon double bond (C═C) which may enable photo curing, and an alkali soluble group which may enable use of an alkali developing solution. A content of the alkali soluble resin A may be in the range of about 30 to about 95% by weight, or 50 to about 80% by weight, or about 55 to about 75% by weight, based on the total weight of the patternable adhesive composition exclusive of the solvent, if present. When the content of the alkali soluble resin A exceeds the above range, the adhesiveness may be deteriorated. When it is less than the above range, the developing rate may be reduced, thus patternability may be degraded.

When a weight-average molecular weight (MW) of the alkali soluble resin A is about 5 kiloDaltons (kDa) or less, formability of the film may be impaired, and when it is about 20 kDa or more the solubility of the alkali soluble resin A in the alkali developing solution may be reduced. Also, when a glass transition temperature of the alkali soluble resin is less than about 100° C., a glass transition temperature of the patternable adhesive composition in the absence of a solvent, for example a film formed using the patternable adhesive composition may be about 30° C., and thus a gap may form during a thermal lamination and compression bonding processes. Accordingly, the alkali soluble resin A may include at least one polymer which has a weight-average molecular weight of about 5 to about 30 kDa, or about 7 to about 18 kDa, or about 9 to about 16 kDa, and a glass transition temperature of about 100° C. or more. In an embodiment, the alkali soluble resin A may include more than one polymer having the foregoing characteristics, for example two or three polymers, each having a weight-average molecular weight of about 5 to about 20 kDa, or about 7 to about 18 kDa, or about 9 to about 16 kDa, and a glass transition temperature of about 100° C. or more. Other co-curable polymers having different weight-average molecular weights and/or glass transition temperatures may be present in the alkali soluble resin A, provided that the formability is not impaired, the solubility in the developing solution is not impaired, and the total patternable adhesive composition, in the absence of a solvent, for example a film formed using the patternable adhesive composition, has a Tg of about 50° C. or higher. For example, the alkali soluble resin A may comprise one or more other co-curable polymers having different weight-average molecular weights and/or glass transition temperatures in amounts from 0 to about 10 wt %, based on the total weight of the alkali soluble resin A.

In an embodiment, the alkali soluble resin A may has a weight-average molecular weight of about 5 to about 20 kiloDaltons, or about 7 to about 18 kDa, or about 9 to about 16 kDa and a glass transition temperature of about 100° C. or higher, or about 100 to about 150° C., or about 110 to about 140° C., and comprise at least one component selected from an acryl polymer comprising a carboxylic ester group and an acryloyl group, a urethane acryl oligomer comprising a carboxylicgroup and an acryloyl group, a novolac acryl oligomer comprising a carboxylic group and an acryloyl group.

According to an embodiment, the alkali soluble resin A may contain a combination of all of above, i.e., a combination of the acryl polymer, the urethane acryl oligomer, and the novolac acryl oligomer. As used herein, “carboxyl group” encompasses groups of the formula —C(O)X wherein X is an alkali soluble group in the presence of the developing solution. The carboxyl group may accordingly be a carboxylic ester group, or a carboxylic acid.

The urethane acryl oligomer may impart flexibility to a film formed from the patternable adhesive composition, and the novolac acryl oligomer may impart rigidity to the film core. When the alkali soluble resin A contains both the urethane acryl oligomer and the novolac acryl oligomer, the alkali soluble resin A may have suitable flexibility and rigidity, and the film may have good filmability which may substantially or effectively prevent bubbling or tenting during lamination.

The alkali soluble group may be a carboxylic group. The alkali soluble resin A may have an acid value of about 30 to about 100 milligrams potassium hydroxide per gram (mgKOH/g), or about 40 to about 90 mgKOH/g, or about 50 to about 80 mgKOH/g. When the acid value of the alkali soluble resin A is less than about 30 mgKOH/g, the solubility of a non-exposed portion of a film in an alkali developing solution is lowered, thus patternability may degrade. When it exceeds more than about 100 mgKOH/g, the exposed portion of the film may collapse. When the patternable adhesive composition comprises at least one alkali soluble resin A, the patternable adhesive composition may have a total acid value of about 30 to about 80 mgKOH/g, or about 40 to about 60 mgKOH/g, or about 45 to about 55 mgKOH/g.

The acryloyl-group equivalent weight of the alkali soluble resin A is not especially limited. However, it is difficult to prepare the alkali soluble resin A having an acryloyl-group equivalent weight of about 300 grams per equivalent mole (g/eq.mol) or less. Also, when the alkali soluble resin A has a high acryloyl-group equivalent weight, e.g., an acryloyl-group equivalent weight of 1000 g/eq.mol or more, photo curing may be incomplete. Accordingly, the alkali soluble resin A may have an acryloyl-group equivalent weight of about 200 to about 600 g/eq.mol, or about 300 to about 500 g/eq.mol, or about 350 to about 550 g/eq.mol.

The alkali soluble resin A is not especially limited so long as it has both an alkali soluble group and acryloyl group. The alkali soluble group and unsaturated double bond for radical curing may be present along the backbone of the resin or located on a side chain, for example on a graft. For example, the alkali soluble resin A may be a resin which has both an alkali soluble carboxylic group and a radical-curable acryloyl group. For example, the alkali soluble resin A may be derived from the polymerization of a radical-curing acrylate, which may be at least one selected from methyl(meth)acrylate, ethyl(meth)acrylate, butyl(meth)acrylate, isobutyl(meth)acrylate, 2-ethylhexyl(meth)acrylate, isooctyl(meth)acrylate, glycidyl(meth)acrylate, cyclohexyl(meth)acrylate, isobornyl(meth)acrylate, benzyl(meth)acrylate, 2-hydroxy(meth)acrylate, trimethoxybutyl(meth)acrylate, ethylcarbitol(meth)acrylate, phenoxyethyl(meth)acrylate, 2-hydroxyethyl(meth)acrylate, trimethylolpropanetri(meth)acrylate, tetramethylolmethane tetra(meth)acrylate, pentaerythritolhexa(meth)acrylate, pentaerythritoltetra(meth)acrylate, dipentaerythritol monohydroxypenta(meth)acrylate, dipentaerythritol hexa(meth)acrylate, 1,4-butylene glycol di(meth)acrylate, 1,6-hexanediol di(meth)acrylate, polyethylene glycol di(meth)acrylate, oligoester(meth)acrylate, multifunctional urethane(meth)acrylate, urea acrylate, and the like, but is not limited thereto.

### Radically Polymerizable Compound B

The radically polymerizable compound B may be a multifunctional acryl monomer having at least two acryloyl groups. For example, the radically polymerizable acrylate monomer B may be at least one selected from isobornyl(meth)acrylate, 1,6-hexanediol diacrylate, triethylene glycol diacrylate, trimethylolpropane triacrylate, tetraethylene glycol diacrylate, 1,3-butanediol diacrylate, neopentyl glycol diacrylate, pentaerythritol triacrylate, and dipentaerythritol hydroxypentacrylate, and the like, but is not limited thereto.

A content of the radically polymerizable compound B may be in the range of about 0.1 to about 20% by weight, or about 1 to about 10% by weight, or about 2 to about 8% by weight, based on the total weight of the patternable adhesive composition exclusive of the solvent, if present. When the content of the radically polymerizable compound B exceeds the above range, the patternable adhesive composition may become too tacky to handle. When it is less than the above range, crosslinking may be insufficiently formed during a photo-curing process.

### Thermosettable Resin C

The thermosettable compound may be a commercially available multifunctional epoxy resin having at least two epoxy groups in the molecule. For example, the epoxy resin may be at least one selected from a bisphenol A epoxy resin, a bromized epoxy resin, a novolac epoxy resin, a phenol-novolac epoxy resin, a cresol-novolac epoxy resin, a bisphenol F epoxy resin, a hydrogenated bisphenol A resin, a glycidyl amine epoxy resin, an alicyclic epoxy resin, a trihydroxy phenylmethane epoxy resin, a bixylenol or biphenol epoxy resin, a bisphenol S epoxy resin, a bisphenol A novolac epoxy resin, a tetraphenylol ethane epoxy resin, a diglycidyl phthalate resin, a naphthalene-group-containing epoxy resin, and an epoxy resin having a dicyclopentadiene backbone.

When a content of the thermosettable compound C is high, e.g., greater than about 60% by weight, based on the total weight of the patternable adhesive composition exclusive of the solvent if present, the non-exposed portion of a film may be insufficiently developed, and patternability may be degraded. When the content of the thermosettable compound C is low, e.g., less than about 1% by weight, based on the total weight of the patternable adhesive composition exclusive of the solvent if present, the adhesiveness may be deteriorated. Accordingly, in an embodiment the thermosettable compound C may be contained in the range of about 5 to about 40% by weight, based on the total weight of the patternable adhesive composition exclusive of the solvent if present.

The thermosettable compound C may include both a solid phase thermosettable compound, which is a solid at room temperature (e.g., about 20° C.), and a liquid phase thermosettable compound, which is a liquid at room temperature (e.g., about 20° C.). The solid phase thermosettable compound may have low elution characteristics and thus may maintain adhesiveness of the exposed portion of a film in an alkali developing solution. However, the solubility of the non-exposed portion of a film in the alkali developing solution may be reduced, and thus patternability may be degraded. On the other hand, the liquid phase thermosettable compound may reduce a solubility resistance of the non-exposed portion of a film in the alkali developing solution, but the liquid phase thermosettable compound may be eluted by the alkali developing solution in the exposed portion of a film, and thus may deteriorate adhesiveness in the exposed portion of a film. Accordingly, when a combination of the solid phase thermosettable compound and the liquid phase thermosettable compound is used, the patternable adhesive composition may exhibit improved patternability and adhesiveness.

For example, the solid phase thermosettable compound may be a multifunctional epoxy compound having a softening point of 100° C. or higher, or about 100 to about 200° C., or about 110 to about 180° C. For example, when the solid phase thermosettable compound comprises a triphenyl group, the solid phase thermosettable compound may comprise at least one selected from a phenol novolac epoxy and a cresol epoxy.

The liquid phase thermosettable compound may be a multifunctional epoxy, which is a liquid at room temperature (e.g., about 20° C.). For example, the liquid phase thermosettable compound may be a monomer having a core, and may be a bisphenol A or a naphthalene.

Although a ratio of the solid phase thermosettable compound to the liquid phase thermosettable compound is not especially limited, as the content of the liquid phase thermosettable compound is increased, the photosensitivity and the solubility in the alkali solvent of the patternable adhesive composition may increase. However, when the thermosettable compound C contains only a liquid epoxy, the adhesiveness of the liquid epoxy may be reduced due to elution of the liquid epoxy by the developing solution in the surface of the exposed portion. Also, as the content of the solid phase thermosettable compound is increased, the adhesiveness of the patternable adhesive composition may increase. However, when the total content of the thermosettable compound C is in the range of 20% or more and it contains only a solid epoxy, the developing rate may be reduced, thus patternability may be degraded. Therefore, the content of the solid phase thermosettable compound may be in the range of about 2 to about 35% by weight, or 4 to about 30% by weight, or 6 to about 25% by weight, based on the total weight of the patternable adhesive composition exclusive of the solvent if present.

### Photo-Radical Initiator D

The photo-radical initiator D may comprise a compound which generates a radical upon ultraviolet (“UV”) irradiation. For example, the photo-radical initiator D may be at least one selected from 2,2′-azobisisobutyronitrile, 2,2′-azobis(2,4-dimethylvaleronitrile)), 2,2′-azobis(4-methoxy 2,4-dimethylvaleronitrile), 1,1′-azobis(cyclohexane-1-carbonitrile), dimethyl 2,2′-azobisisobutylate, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, methyl benzoylformate, α,α-dimethoxy-α-phenylacetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl (2,4,6-trimethylbenzoyl)-phosphine oxide, and phosphine oxide.

The patternable adhesive composition may contain about 1 to about 5% by weight of the photo-radical initiator D, based on the total weight of the patternable adhesive composition exclusive of the solvent if present. When a content of the patternable adhesive composition is more than 5% by weight, preparation costs may increase because the photo-radical initiator D is expensive. When it is less than 1% by weight, crosslinking during photo curing may not be sufficient.

### Additive E

A patternable adhesive composition according to an embodiment may further comprise at least one additive selected from a curing agent, a curing accelerator, a catalyst, a photo-acid generator, a coupling agent, and a filler. Other additives may be included, so long as they do not adversely affect the desirable properties of the patternable adhesive composition.

The curing agent may comprise at least one selected from a phenolic compound, aliphatic amine, alicyclic amine, aromatic polyamine, polyamide, aliphatic acid anhydride, alicyclic acid anhydride, aromatic acid anhydride, dicyandiamide, a trifluoroborane complex, imidazole, and tertiary amine.

The curing agent may be a phenolic compound, which may have good developability in an organic solvent and at least two phenolic hydroxyl groups in the molecule. For example, the curing agent may comprise at least one selected from a phenol novolac resin, a cresol novolac resin, a t-butyl phenol novolac resin, a xylene-modified novolac resin, a naphthol novolac resin, a tris(phenol) novolac resin, a tetrakis phenol novolac resin, a bisphenol A novolac resin, a poly-p-vinyl phenol resin, a phenol aralkyl resin, a tris(phenol) compound, and the like.

The curing accelerators and catalysts, if present, are not especially limited, so long as they may promote the curing of an epoxy resin. For example, the curing accelerator or catalyst may each independently comprise at least one selected from an imidazole, a dicyandiamide compound, dicarboxylic acid dehydride, triphenyl phosphine, tetraphenyl phosphonium, tetraphenylborate, 2-ethyl-4-methylimidazole-tetraphenylborate, and the like.

The photo-acid generator may be a compound that can generate an acid during ultraviolet (“UV”) irradiation to partially cure an epoxy resin. The photo-acid generator may be selected from an aromatic iodonium salt and an aromatic sulfonium salt. For example, the photo-acid generator may be at least one selected from di(t-butylphenyl)iodonium triplate, diphenyliodonium tetrakis(pentafluorophenyl)borate, diphenyliodonium hexafluorophosphate, diphenyliodonium hexafluoroantimonate, di(4-nonylphenyl)iodonium hexafluorophosphate, [4-(octyloxy)phenyl]phenyliodonium hexafluoroantimonate, triphenylsulfonium triplate, tri phenylsulfonium hexafluorophosphate, triphenylsulfonium hexafluoroantimonate, tri phenylsulfonium tetrakis(pentafluorophenyl)borate, 4,4′-bis[diphenylsulfonium]diphenylsulfide, bis-hexafluorophosphate, 4,4′-bis[di(β-hydroxyethoxy)phenylsulfonium]diphenylsulfide bis-hexafluoroantimonate, 4,4′-bis[di(β-hydroxyethoxy)(phenylsulfonium)]diphenyl sulfide bishexafluorophosphate, 7-[di(p-toyl)sulfonium]-2-isopropylthioxanthone hexafluorophosphate, 7-[di(p-toyl)sulfonio-2-isopropylthioxanthone hexafluoro antimonate, 7-[di(p-toyl)sulfonium]-2-isopropyl tetrakis(pentafluorophenyl)borate, phenylcarbonyl-4′-diphenylsulfonium diphenylsulfide hexafluorophosphate, phenylcarbonyl-4′-diphenylsulfonium diphenylsulfide hexafluoroantimonate, 4-tert-butylphenylcarbonyl-4′-diphenylsulfonium diphenylsulfide hexafluorophosphate, 4-tert-butylphenylcarbonyl-4′-diphenylsulfonium diphenylsulfide hexafluoroantimonate, 4-tert-butylphenylcarbonyl-4′-diphenylsulfonium diphenylsulfide tetrakis(pentafluorophenyl)borate, and diphenyl[4-(phenylthio)phenyl]sulfonium hexafluoroantimonate, and the like. When a content of the photo-acid generator is less than about 0.1 parts by weight, it may be difficult to obtain sufficient photocuring. When it exceeds about 10 parts by weight, photocuring may be impaired by light absorption by the photo-acid generator itself.

In an embodiment, the patternable adhesive composition may comprise a coupling agent which may provide increased adhesive strength. For example, the coupling agent may comprise at least one selected from a silane coupling agent such as γ-methacryloxypropyltrimethoxysilane, vinyltriacetoxysilane, vinyltrimethoxysilane, γ-isocyanatepropyltriethoxysilane, γ-glycidoxypropyltrimethoxysilane, and β-(3,4-epoxycyclohexyl)ethyltrimethoxysilane. The coupling agent may impart high adhesive strength to the photosensitive adhesive composition.

In addition, the patternable adhesive composition may comprise an organic or inorganic filler. For example, the filler may comprise at least one selected from an inorganic filler, such as silica, alumina, boron nitride, titanium dioxide, glass, iron oxide, boron aluminum, and ceramic, and a rubber filler.

The patternable adhesive composition may be used to provide a film having a high shear bond strength of about 3 kgf/25 mm² or higher or about 8 kgf/25 mm² or higher during photo radical curing at a temperature of about 260° C., at which a solder bonding process is enabled and during a hard baking process, which may comprise a temperature of about 175° C. for about 2 hours. Accordingly, since the patternable adhesive composition exhibits suitable adhesiveness at a temperature of about 240 to about 260° C., which may correspond to a melting point of a solder, the patternable adhesive composition may be effectively used in a through silicon via (“TSV”) method by which semiconductor dies may be connected to one another by bonding through the electrodes using the solder.

Furthermore, the non-exposed portion of the film may be developed at an alkali developing rate of about 0.1 μm/sec. For example, after exposing a portion of the photosensitive adhesive film of the patternable adhesive composition to a radiation source, the non-exposed portion may have a dissolution rate of about 0.1 μm/sec or higher, or 0.1 to 10 μm/sec, or 0.5 to 5 μm/sec when contacted with a 2.38% by weight TMAH developing solution. Although a developing time may be arbitrarily selected, as the developing time increases, the exposed portion is in contact with the developing solution for a longer time and may be damaged by the developing solution, thus patternability may be degraded. Also, when the developing time is short, it may be difficult to provide sufficient uniformity. Thus when the developing time is short, it is difficult to provide an acceptable deviation between a difference in developing thickness relative to a point-to-point position of a 12-inch wafer and a deviation in developing thickness caused by process variability, such as a time deviation of developing equipment, and thus the entire pattern may not have sufficient uniformity. Thus, the film may have a dissolution rate of about 0.1 μm/sec or higher or about 0.4 μm/sec or higher, or about 0.1 to about 5%, or about 0.5 to about 4%, when contacted with a 2.38% by weight TMAH developing solution. For example, the time taken to completely dissolve the non-exposed portion of the film in the negative photoresist with a thickness of 20 μm may be about 200 seconds at a developing rate of about 0.1 μm/sec and about 50 seconds at a developing rate of 0.4 μm/sec.

When the non-exposed portion of the film is dissolved at the above rate, patternability is improved, and fine patterns having sufficient resolution and uniformity may be formed. Accordingly, it may be possible to accommodate a reduced pitch, e.g., a pitch of 100 μm or less of through electrodes and have at least 500 through electrodes in an overhead of a given area.

Furthermore, as explained above, a variation in the thickness of the exposed portion of the film may be less than 5% after developing the exposed portion. When the thickness variation of the exposed portion is 5% or more, the exposed portion may be undesirably damaged by the developing solution, and thus the surface of the resulting film may not properly function as an adhesive surface.

The patternable adhesive film according to an embodiment may be patterned such that the patternable adhesive film may be interposed between stacked semiconductor dies to bond through electrodes using solders by a 3-dimensional stacked package technique. Also, after the solder bonding process and a post baking process, the patternable adhesive film may have such an adhesive strength as to pass a package reliability test. That is, after being heated at a temperature of about 260° C., the patternable adhesive film may have a shear bond strength of about 3 kgf/25 mm² or higher, or about 8 kgf/25 mm² or higher, thereby preventing a short between electrodes due to debonding or bulk cracks.

According to another embodiment, a semiconductor die for a semiconductor package is provided.

FIG. 6 is a cross-sectional view of a semiconductor die for a semiconductor package according to an embodiment. Referring to FIG. 6, a first pattern adhesive layer 510, on which a pattern is formed, is disposed on a front surface of the semiconductor die for the semiconductor package, and through electrodes having solder bumps are disposed in the pattern. Also, a second pattern adhesive layer 520, on which a pattern is formed, is disposed on a rear surface of the semiconductor die for the semiconductor package, and pads of reinterconnected through electrodes are disposed in the pattern. The thickness of the second photosensitive pattern adhesive layer may be about ⅕ to about 1 times that of the first photosensitive pattern adhesive layer for the same reasons as above.

According to another embodiment, a semiconductor die for a semiconductor package may comprise a second pattern adhesive layer having a pattern, which is disposed on a rear surface thereof without forming a first pattern adhesive layer on a front surface thereof. The pattern of the second pattern adhesive layer may comprise pads of the through electrodes reinterconnected in the pattern.

In manufacture of the semiconductor die for the semiconductor package, a transparent support is removed, and the second pattern adhesive layer having the pattern is formed on the reinterconnected rear surface of the semiconductor die. Accordingly, even when the semiconductor die for the semiconductor package is exposed to a UV irradiation or reinterconnected process during a semiconductor package preparation process, the second pattern adhesive layer may still exhibit adhesiveness. When the semiconductor die is applied to a semiconductor stack package, a plurality of layers, such as more than two layers, may be stacked. For example, four-layer, eight-layer, and sixteen-layer semiconductor stack packages may be fabricated. Accordingly, integration limitations caused by the shrinkage of line widths, particularly, in memory fields, can be overcome by providing 3-dimensional stack structures.

Furthermore, the method of preparing the semiconductor package and the semiconductor die for the semiconductor package may be applied not only to homogeneous dies of memory devices but also to heterogeneous dies of non-memory devices.

Hereinafter, the exemplary embodiments will be described in further detail with reference to Preparation Examples, Comparative Examples and Experimental Examples. The following examples are merely to explain the exemplary embodiments, and shall not limit the disclosed embodiments.

### Preparation Example

A composition for forming a patternable adhesive film is prepared using 25 parts by weight of ACA-251AA (Daicel Chemical) as a main alkali soluble resin component), 30 parts by weight of CCR-1291H (Nippon Kayaku) and 5 parts by weight of UXE-3024 (Nippon Kayaku) as an acryl oligomer, 5 parts by weight of trimethylolpropane triacrylate (“TMPTA”) (Sartomer) as an acryl monomer, 20 parts by weight of EPPN-501H (Nippon Kayaku) as a solid epoxy and 5 parts by weight of bisphenol A diglycidyl ether (BPA-DG) (SigmaAldrich) as a liquid epoxy, 10 parts by weight of MEH-7800 (Meiwa) as a curing agent, 1.5 parts by weight of Irgacure 369 (Ciba Specialty Chemicals) and 1.5 parts by weight of 1.5 parts by weight of Irgacure 819 (Ciba Specialty Chemicals) as a photo-initiator, and 1.5 parts by weight of triarylsulfonium hexafluoroantimonate salts (SigmaAldrich) as a photo-acid generator, are mixed and dissolved in a propyleneglycol methyletheracetate (“PGMEA”) solution to a total solid content of 40% by weight. The composition is applied on a PET film whose surface is treated with a silicone-based releasing agent, dried in a forced convection oven at a temperature of about 85° C. for about 20 minutes to prepare a patternable adhesive film for forming a pattern which has a thickness of 5 μm, 20 μm, and 25 μm. Here, the thickness of the film may depend on the heights of bumps and solders disposed on the front and rear surfaces of the semiconductor die.

### Example 1

The prepared 20 μm patternable adhesive film is laminated on a wafer having a height of 12 μm, a solder height of 8 μm, a diameter of 20 μm, and a pitch of 40 μm, on which through electrodes are arranged, at a roll temperature of about 65° C., and a pre-exposure baking process is performed at a temperature of about 100° C. for about 2 minutes. The laminated wafer is irradiated by UV light with a wavelength of 365 nm using a photomask having shadowed electrode portions with the same arrangement as the through electrodes, and a post-exposure baking process is performed at a temperature of about 100° C. for about 2 minutes. The resulting structure is developed by spinning using a 2.38% by weight TMAH alkali developing solution at a temperature of about 25° C. for about 60 seconds, and cleaned with deionized water (“DIW”), and then dried, to form a pattern having 95% of the dimension linearity on a photomask. In this case, it is confirmed that soldered portions are opened in hole portions of the patterned adhesive film.

A glass wafer is bonded to the patterned adhesive film laminated on the wafer, the opposite rear surface of the wafer is lapped to open the through electrodes to a thickness of 3 μm, and a metal layer pattern required for interconnecting the through electrodes is disposed by a sputtering process and passivated by a chemical vapor deposition (“CVD”) process. The sputtering and CVD processes are performed at a peak temperature of about 200° C. or lower for about 10 minutes. The prepared 5-μm patternable adhesive film is laminated at a roll temperature of about 65° C. on the rear surface of the wafer on which the through electrodes are reinterconnected, and a pre-exposure baking process is performed at a temperature of about 100° C. for about 2 minutes. The resulting structure is irradiated by UV light with a wavelength of 365 nm using a photomask having shadowed electrode portions with the same arrangement as the reinterconnected electrodes disposed on the rear surface of the wafer, and a post-exposure baking process is performed at a temperature of about 100° C. for about 2 minutes. The resulting structure is developed by spinning with a 2.38% by weight TMAH alkali developing solution at room temperature for about 40 seconds, cleaned with DIW, and dried, to form a pattern having 95% of the dimension linearity on a photomask. In this case, it is confirmed that the reinterconnected electrodes are opened in hole portions of the patterned adhesive film. Subsequently, a dicing tape is bonded to the rear surface of the wafer having the pattern, the temporary adhesive film to which the glass wafer is bonded is removed with UV irradiation, and the wafer is diced into semiconductor dies. Thereafter, adhesive strength between the dicing tape and the semiconductor dies is removed with UV irradiation to facilitate the pickup of the semiconductor dies. Each of first and second semiconductor dies has a front surface on which the patternable adhesive film is disposed, bumps are provided in through electrodes disposed in the pattern, solders are provided on the bumps and a rear surface on which the patternable adhesive film is disposed, and through electrodes are reinterconnected in the pattern. The front surface of the first semiconductor die is bonded to the rear surface of the second semiconductor die and compressively bonded under a pressure of about 1 kgf at a temperature of about 260° C. for about 10 seconds.

### Example 2

Example 2 is performed by the same method as in Example 1, except that the prepared 25 μm patternable adhesive film is laminated on the rear surface of the wafer on which the through electrodes are reinterconnected, without laminating the prepared patternable adhesive film on the front surface of the wafer.

### Comparative Example 1

Comparative Example 1 is performed by the same method as in Example 1, except that the prepared 25 μm patternable adhesive film is laminated on the front surface of the wafer without laminating the prepared patternable adhesive film on the opposite rear surface of the wafer on which the through electrodes are reinterconnected.

### Experimental Example 1

Samples of the semiconductor packages prepared according to Examples 1 and 2 and Comparative Example 1 are hard-baked at a temperature of about 175° C. for about 2 hours. While applying a shear strength at a shear rate of about 100 μm/s, the maximum shear strengths at which bonded surfaces of at least ten samples are detached are measured by a shear strength measurement apparatus on a hot plate maintained at a temperature of about 260° C., and the average values are presented in Table 1.

TABLE 1

| | | | | Comparative |
|---|---|---|---|---|
| Item | Conditions | Example 1 | Example 2 | Example 1 |
| Adhesive strength | 5 × 5, 260° C., | 10.5 | 10.1 | 1.8 |
| (kgf) | 100 μm/s | | | |

As shown in Table 1, the samples prepared according to Examples 1 and 2 in which the patternable adhesive films are laminated on both surfaces of the wafer have high adhesive strengths of 10.5 and 10.1, while the sample prepared according to Comparative Example 1 in which the adhesive film is laminated on only one surface of the wafer has a very low adhesive strength of 1.8.

The disclosed embodiments shall not be construed as being limited to the embodiments set forth herein. Rather, these embodiments are provided so that this disclosure will be thorough and complete and will fully convey the concept of the present invention to those of ordinary skill in the art.

While the invention has been particularly shown and described with reference to embodiments thereof, it will be understood by those of ordinary skill in the art that various changes in form and details may be made therein without departing from the spirit or scope of the present invention as defined by the following claims.

What is claimed is:

1. A method of preparing a semiconductor package, the method comprising:
disposing a photosensitive adhesive film on a reinterconnected rear surface of a wafer on which through electrodes are disposed; and
forming a pattern corresponding to the through electrodes to prepare the semiconductor package.

2. The method of claim 1, further comprising:
temporarily bonding a transparent support to a front surface of the wafer on which the through electrodes are disposed;
lapping an opposite rear surface of the wafer;
reinterconnecting the opposite rear surface of the wafer;
laminating a second photosensitive adhesive film on the reinterconnected rear surface of the wafer;
exposing and alkali developing the second photosensitive adhesive film to form a pattern corresponding to the through electrodes;
bonding a dicing tape to the rear surface of the wafer on which the pattern of the second photosensitive adhesive film is formed;
detaching the transparent support from the front surface of the wafer;
dicing the wafer to form a plurality of semiconductor dies;
removing the dicing tape; and
stacking and bonding the plurality of semiconductor dies.

3. The method of claim 2, further comprising, before the lapping and reinterconnecting of the opposite rear surface of the wafer,
laminating a first photosensitive adhesive film on the front surface of the wafer on which the through electrodes are disposed, and
exposing and alkali developing the first photosensitive adhesive film to form a pattern corresponding to the through electrodes.

4. The method of claim 2, further comprising:
pre-baking at a temperature of about 60 to about 140° C. for about 1 to about 30 minutes before the exposing; and
post-baking at a temperature of about 60 to about 140° C. for about 1 to about 30 minutes after the exposing.

5. The method of claim 1, wherein the pattern has a diameter of about 200 micrometers or less, an aperture ratio of less than about 5 percent, and about at least 100 openings.

6. The method of claim 2, wherein the second photosensitive adhesive film has a thickness of about ⅕ to about 1 times that of the first photosensitive adhesive film.

7. The method of claim 1, wherein the reinterconnecting of the opposite rear surface of the wafer comprises
forming a metal layer pattern, and then
passivating the metal layer pattern using a chemical vapor deposition process.

8. The method of claim 2, wherein the through electrodes have solder bumps disposed on top ends thereof, and the stacking and bonding of the plurality of semiconductor dies comprises:
stacking the plurality of semiconductor dies on each other;
bonding the plurality of dies to one another by soldering the through electrodes at a temperature of about 260° C.; and
simultaneously thermally curing the first and second photosensitive adhesive films.

9. The method of claim 8, wherein the bonding of the plurality of dies to one another is performed for about 30 seconds or less under a pressure of about 0.1 to about 10 kilograms force.

10. The method of claim 2, further comprising, after the stacking and bonding of the plurality of dies, treating the bonded semiconductor dies with an epoxy molding compound, and then hard-baking at a temperature of about 150 to about 190° C. for about 1 to about 3 hours.

11. The method of claim 1, wherein the first and second photosensitive adhesive films are disposed using a patternable adhesive composition, the patternable adhesive composition comprising:
at least one alkali soluble resin comprising an alkali soluble group and an acryloyl group;
at least one radically polymerizable compound;
at least one thermosettable compound; and
at least one photo-radical initiator.

12. The method of claim 11,
wherein the alkali soluble resin has a weight-average molecular weight of about 5 to about 20 kiloDaltons and a glass transition temperature of about 100° C. or higher,
the at least one alkali soluble resin has an acid value of about 30 to about 100 milligrams KOH per gram,
the patternable adhesive composition has a total acid value of about 40 to about 60 milligrams potassium hydroxide per gram; and
the photosensitive adhesive film has a dissolution rate of about 0.1 micrometer per second or higher when contacted with a 2.38 percent by weight tetramethylammoniumhydroxide developing solution, and a thickness variation of the exposed portion of the photosensitive adhesive film is less than about 5 percent after an exposing and alkali developing process.

13. The method of claim 11, wherein the at least one alkali soluble resin has a weight-average molecular weight of about 5 to about 20 kiloDaltons and a glass transition temperature of about 100° C. or higher, and
the at least one alkali soluble resin comprises at least one selected from
an acryl polymer comprising a carboxyl group and an acryloyl group,
a urethane acryl oligomer comprising a carboxyl group and an acryloyl group, and
a novolac acryl oligomer comprising a carboxyl group and an acryloyl group.

14. The method of claim 11, wherein the acryloyl group equivalent weight of the alkali soluble resin is about 300 to about 500 grams per equivalent mole.

15. The method of claim 11, wherein the at least one thermosettable compound is both a solid phase thermosettable compound which is a solid at room temperature and a liquid phase thermosettable compound which is a liquid at room temperature.

16. The method of claim 15, wherein the solid phase thermosettable compound is a multifunctional epoxy compound having a softening point of about 100° C. or higher, and a content of the solid phase thermosettable compound is in the range of about 2 to about 35 percent by weight, based on a total weight of the patternable adhesive composition.

17. The method of claim 11, wherein the photosensitive adhesive filmhas a shear bond strength of about 3 kilograms force per 25 square millimeters or more after curing at a temperature of about 260° C.

18. The method of claim 11, wherein, when an exposed portion of the first and second photosensitive adhesive films is exposed for about 200 seconds at a radiation dose of about 500 to about 3000 milliJoules per square centimeter at a wavelength of about 365 nanometers using an i-line of a Hg lamp and developed, a thickness variation of the exposed portion of the developed film is less than 5 percent.

19. A semiconductor die for a semiconductor package, the semiconductor die comprising:
a first pattern adhesive film disposed on a front surface; and
a second pattern adhesive layer comprising a patternand disposed on an opposite reinterconnected rear surface thereof,
wherein pads of through electrodes are reinterconnected in the pattern.

20. The semiconductor die of claim 19, wherein solder bumps of the through electrodes are disposed in the first pattern adhesive layer.
